(19) United States
(12) Patent Application Publication
(10) Pub. No.: US 2025/0311486 A1
(43) Pub. Date: Oct. 2, 2025

(54) LIGHT-EMITTING DIODE AND LIGHT-EMITTING DEVICE

(71) Applicant: Tianjin Sanan Optoelectronics Co., Ltd., Tianjin (CN)

(72) Inventors: Zhiwei WU, Tianjin (CN); Yanyun WANG, Tianjin (CN); Jingjing LI, Tianjin (CN); Huanshao KUO, Tianjin (CN); Yuren PENG, Tianjin (CN)

(21) Appl. No.: 19/095,109

(22) Filed: Mar. 31, 2025

(30) Foreign Application Priority Data
Apr. 2, 2024 (CN) 2024103969063

(51) Int. Cl. H10H 20/816; F21V 19/00; H10H 20/814; H10H 29/49

(52) U.S. Cl. CPC H10H 20/816; F21V 19/0025; H10H 20/814; H10H 29/49

(57) ABSTRACT

A light-emitting diode and a light-emitting device are provided. The light-emitting diode defines that a distance between geometric centers of adjacent platform regions in the current spreading layer is equal, that is, a circle is drawn with a geometric center of any platform region as a center and the distance between the geometric centers of adjacent platform regions as a radius, and centers of adjacent platform regions are located on the circle. Thus, the adjacent platform regions form a complementary pattern when current spreads. Taking one platform region as an example, an overlapping area of the current spread between any adjacent platform regions is equal, thereby achieving an effect of uniform current diffusion. In addition, formation of the recessed regions correspondingly reduce a content of the current spreading layer (such as GaP), thereby reducing the light absorption of the current spreading layer and increasing the light-emitting rate of the chip.

### CROSS-REFERENCE TO RELATED APPLICATION

This application claims priority to Chinese Patent Application No. 202410396906.3, filed on Apr. 2, 2024, which is herein incorporated by reference in its entirety.

### TECHNICAL FIELD

The disclosure relates to the technical field of semiconductor optoelectronic devices, and more particularly to a light-emitting diode and a light-emitting device.

### BACKGROUND

Light-emitting diode (LED) is a semiconductor device that uses the energy released when carriers recombine to generate light. The light-emitting diode is considered to be one of the most promising light sources at present due to its advantages such as high light-emitting intensity, high efficiency, small size and long service life.

Existing light-emitting diodes include horizontal and vertical types. Electrodes of the vertical type light-emitting diode are disposed on a top and a bottom of the chip respectively, and the current is allowed to flow vertically through the LED chip. Compared with the horizontal type, the vertical type can effectively improve technical problems such as light absorption, current crowding or poor heat dissipation caused by the epitaxial growth substrate. When current is injected into the electrode at the top of the chip, the current will be transmitted from the electrode to multiple current transmission blocks located in the chip, and then flow from the current transmission blocks to the electrode at the bottom of the chip, thereby ensuring uniform current distribution and avoiding current accumulation.

However, since each current transmission block is in a shape of a dot, the process of current transmission from the electrode to the current transmission blocks has the following defects. 1. A current transmission direction is an arc in space, which greatly limits the transmission of current, and since a side cross-sectional area of each current transmission block is limited, the current transmitted per unit time is also limited. 2. The current will gather on a narrow side cross-section of each current transmission block, and the current and heat cannot be transferred quickly, resulting in high forward voltage, low cold-hot current ratio coefficient, and poor thermal measurement saturation. Therefore, how to solve the above problems to optimize the current transmission effect is one of the technical problems that those skilled in the art need to solve urgently.

### SUMMARY

In view of the shortcomings and defects of LED chips in the related art in terms of current spreading, the disclosure provides a light-emitting diode and a light-emitting device. In the light-emitting diode of the disclosure, a patterned current spreading layer and a patterned ohmic contact layer are formed, thereby reducing light absorption of the two on the chip, and improving the light-emitting efficiency. At the same time, uniformity of current spreading is enhanced by controlling the patterned specific structure.

According to the first aspect of the disclosure, the disclosure provides a light-emitting diode, including a semiconductor epitaxial stack layer, a current spreading layer, an ohmic contact layer, a light-transmissive dielectric layer, and a reflecting layer.

The semiconductor epitaxial stack layer has a first surface and a second surface opposite to each other, and includes a first conductivity type semiconductor layer, an active layer and a second conductivity type semiconductor layer in a direction from the first surface to the second surface. The first surface is a light-emitting surface. The current spreading layer is located on a side of the second surface of the semiconductor epitaxial stack layer. The current spreading layer is formed as a pattern current spreading layer, the pattern current spreading layer defines multiple platform regions, and recessed regions are defined around each of the multiple platform regions. The ohmic contact layer is located on a side of the multiple platform regions facing away from the second surface. The light-transmissive dielectric layer is located on a side of the ohmic contact layer facing away from the semiconductor epitaxial stack layer, and is filled into the recessed regions. The light-transmissive dielectric layer has multiple openings to define multiple conductive through holes. The reflecting layer is disposed on the light-transmissive dielectric layer, and is filled into the multiple conductive through holes. The reflecting layer is electrically connected to the ohmic contact layer. A distance between geometric centers of any two adjacent platform regions within the multiple platform regions is equal.

The disclosure defines that the distance between the geometric centers of any two adjacent platform regions in the current spreading layer is equal, that is, a circle is drawn with a geometric center of any platform region as a center and the distance between the geometric centers of the two adjacent platform regions as a radius, and centers of adjacent platform regions are all located on the circle. Thus, the adjacent platform regions form a complementary pattern when the current spreads. Taking one platform region as an example, an overlapping area of the current spread between any adjacent platform regions is equal, thereby achieving the effect of uniform current diffusion. In addition, the formation of the aforementioned recessed regions correspondingly reduce the content of the current spreading layer (such as gallium phosphide abbreviated as GaP), thereby reducing the light absorption of the current spreading layer and increasing the light-emitting rate of the chip.

In an embodiment, a cross-sectional shape of each of the multiple platform regions is a circle or a regular polygon.

The cross-sectional shape of each of the multiple platform regions is the circle or the regular polygon, which can ensure the uniformity of current diffusion from the platform regions to the surrounding regions.

In an embodiment, the distance D between the geometric centers of any two adjacent platform regions within the multiple platform regions is in a range of 10 microns (μm) to 30 μm.

The aforementioned limitation that the distance between the geometric centers of adjacent platform regions can ensure uniform superposition of current diffusion of adjacent platform regions, thereby ensuring uniformity of current diffusion in any region.

In an embodiment, the distance between the geometric centers of any two adjacent platform regions within the multiple platform regions is D, a circle is drawn with a geometric center of any one of the multiple platform regions as a center and the distance D as a radius, geometric centers of 2k of the multiple platform regions are located on the circle, and k is a natural number greater than or equal to 1.

In an embodiment, the cross-sectional shape of each platform region is a circle, and the distance between the geometric centers of any two adjacent platform regions within the multiple platform regions is 1.2 to 3.2 times of a diameter of the circle.

In an embodiment, a projection area of the multiple platform regions on the second surface is 5% to 50% of a surface area of the current spreading layer.

As described above, by limiting the distance between two adjacent platform regions and the relationship between the distance and the diameter of the platform region, and the aforementioned area ratio of the multiple platform regions, the distribution of the multiple platform regions is optimized, thereby ensuring uniform diffusion of current while maximizing the reduction of absorption of the light-emitting of the chip.

In an embodiment, the multiple platform regions are defined in the current spreading layer, and a depth of each of the recessed regions is ⅓ to ⅔ of a thickness of the current spreading layer.

In an embodiment, the multiple platform regions are defined in the current spreading layer, and the depth of each of the recessed regions is equal to the thickness of the current spreading layer.

For different types of LED chips, the depth of each recessed region can be designed according to the semiconductor material forming the chip. For example, in a red-light LED chip, the recessed region can penetrate the current spreading layer (that is, the depth of the recessed region is equal to the thickness of the current spreading layer). For a yellow or green light chips, the depth of the recessed region should be less than the thickness of the current spreading layer.

In an embodiment, the light-emitting diode further includes a first electrode located on a side of the first surface and electrically connected to the first conductivity type semiconductor layer. The first electrode includes a pad electrode and expansion electrodes, the expansion electrodes are distributed on the side of the first surface. When projected toward the first surface, projections of the expansion electrodes and the pad electrode do not overlap with a projection of the multiple platform regions of the current spreading layer.

In an embodiment, the cross-sectional shape of each of the multiple platform regions is a circle, and a minimum spacing distance between the projections of the expansion electrodes and projections of geometric centers of the multiple platform regions is 1.2 to 3.2 times of a diameter of the circle.

In an embodiment, the light-emitting diode further includes a substrate, a metal bonding layer, and a second electrode.

The substrate is located on a side of the reflecting layer facing away from the second surface. The metal bonding layer is located between the substrate and the reflecting layer. The second electrode is located on a side of the substrate facing away from the second surface, and electrically connected to the second conductivity type semiconductor layer.

In an embodiment, a sidewall of each of the multiple platform regions is a vertical sidewall.

In an embodiment, the sidewall of each of the multiple platform regions is an inclined sidewall.

In an embodiment, an opening size of a side of each of the multiple platform regions facing away from the second surface is smaller than a bottom size of a side of the multiple platform regions proximate to the second surface.

The sidewall of the platform region can also be designed according to the specific structure of the LED chip, thereby increasing the applicability of the platform region in different LED chips.

According to the second aspect of the disclosure, the disclosure provides a light-emitting device, including a circuit board, at least one light-emitting element. The at least one light-emitting element is located on the circuit board, and includes the light-emitting diode of the disclosure.

As described above, the light-emitting diode and the light-emitting device of the disclosure have the following technical effects.

The light-emitting diode of the disclosure defines that the distance between the geometric centers of the two adjacent platform regions in the current spreading layer is equal, that is, a circle is drawn with the geometric center of any one platform region as a center and the distance between the geometric centers of the two adjacent platform regions as a radius, the centers of the adjacent platform regions are located on the circle. Thus, the adjacent platform regions form a complementary pattern when the current spreads. Taking one platform region as an example, an overlapping area of the current spread between any adjacent platform regions is equal, thereby achieving the effect of uniform current diffusion. In addition, the formation of the aforementioned recessed regions correspondingly reduce the content of the current spreading layer (such as GaP), thereby reducing the light absorption of the current spreading layer and increasing the light-emitting rate of the chip.

Meanwhile, different depths of the recessed regions and different sidewall types of the platform regions can be designed according to different types of the LED chip or different semiconductor materials, thereby increasing the applicability of the platform regions.

### BRIEF DESCRIPTION OF DRAWINGS

The features and advantages of the disclosure will be more clearly understood by referring to the accompanying drawings, which are schematic and should not be construed as limiting the disclosure in any way.

FIG. 1 illustrates a schematic structural diagram of a light-emitting diode according to an embodiment 1 of the disclosure.

FIG. 2a illustrates a schematic structural diagram from a top-down perspective of the light-emitting diode according to the embodiment 1 of the disclosure.

FIG. 2b illustrates a schematic structural diagram from a top-down perspective of a light-emitting diode according to another embodiment of the disclosure.

FIG. 3 illustrates a schematic structural diagram from a top-down perspective along a surface of a current spreading layer shown in A1-A1 in FIG. 1 to a first surface.

FIG. 4 illustrates a schematic diagram of relative positions of platform regions of the current spreading layer in FIG. 3.

FIG. 5 illustrates a schematic structural diagram of a current spreading layer of a light-emitting diode according to an embodiment 2 of the disclosure.

FIG. 6 illustrates a schematic structural diagram of a light-emitting diode according to an embodiment 3 of the disclosure.

FIG. 7 illustrates a schematic structural diagram of a light-emitting device according to an embodiment 4 of the disclosure.

### DESCRIPTION OF REFERENCE SIGNS

100—semiconductor epitaxial stack layer; 101—first conductivity type semiconductor layer; 102—second conductivity type semiconductor layer; 103—active layer; 110—first surface; 120—second surface; 200—current spreading layer; 201—recessed region; 202—platform region; 202-1—first circular platform region; 202-2—second circular platform region; 202-3—third circular platform region; 202-4—circumference; 300—ohmic contact layer; 400—light-transmissive dielectric layer; 401—conductive through hole; 500—reflecting layer; 600—metal bonding layer; 700—substrate; 800—first electrode; 801—pad electrode; 802—expansion electrode; 900—second electrode;
10—light-emitting device; 11—circuit board; 12—light-emitting element; 13—circuit layer.

### DETAILED DESCRIPTION OF EMBODIMENTS

In order to make the purpose, technical solutions and advantages of the embodiments of the disclosure clearer, the technical solutions in the embodiments of the disclosure will be clearly and completely described below in conjunction with the drawings in the embodiments of the disclosure. Apparently, the described embodiments are merely some of the embodiments of the disclosure, not all of the them.

In the following embodiments of the disclosure, words indicating directions, such as “up”, “down”, “left”, “right”, “horizontal”, and “vertical” are merely used to enable those skilled in the art to better understand the disclosure and are not to be understood as limiting the disclosure.

### Embodiment 1

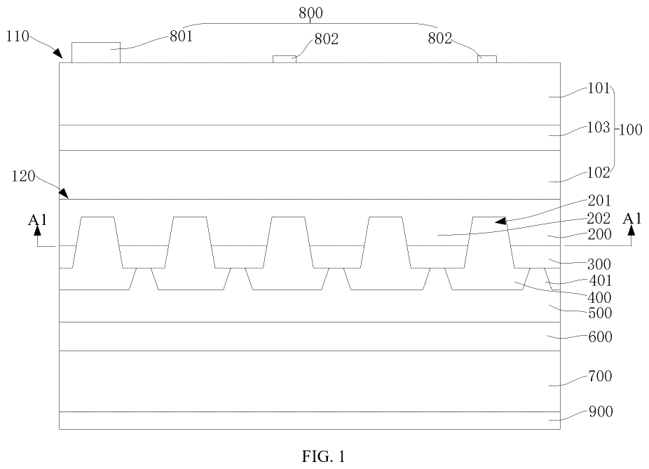

The embodiment provides a light-emitting diode, as shown in FIG. 1, the light-emitting diode of the embodiment includes a semiconductor epitaxial stack layer 100, a current spreading layer 200, an ohmic contact layer 300, a light-transmissive dielectric layer 400, and a reflecting layer 500. The semiconductor epitaxial stack layer 100 has a first surface 110 and a second surface 120, and a side of the first surface 110 is a side of a light-emitting surface of the light-emitting diode. The semiconductor epitaxial stack layer 100 sequentially includes a first conductivity type semiconductor layer 101, an active layer 103 and a second conductivity type semiconductor layer 102 in a direction from the first surface 110 to the second surface 120. The current spreading layer 200 is located on a side of the second surface 120 of the semiconductor epitaxial stack layer 100. The ohmic contact layer 300 is located on a side of the current spreading layer 200 facing away from the second surface 120. The light-transmissive dielectric layer 400 is located on a side of the ohmic contact layer 300 facing away from the second surface 120. The reflecting layer 500 is located on a side of the ohmic contact layer 300 facing away from the second surface 120.

In an embodiment, the aforementioned semiconductor epitaxial stack layer 100 can be formed on a growth substrate through physical vapor deposition (PVD), chemical vapor deposition (CVD), epitaxy growth technology, or atomic layer deposition (ALD). The first conductivity type semiconductor layer 101 and the second conductivity type semiconductor layer 102 are semiconductors having different conductivity types, electrical properties, and polarities, and they provide electrons or holes according to doped elements. For example, when the first conductivity type semiconductor layer 101 is n-type, the second conductivity type semiconductor layer 102 is p-type, and the active layer 103 is formed between the first conductivity type semiconductor layer 101 and the second conductivity type semiconductor layer 102. The electrons and holes recombine in the active layer 103 driven by current, and convert electrical energy into light energy to emit light. A wavelength of the light emitted by the light-emitting diode is adjusted by changing the physical and chemical composition of one or more layers of the epitaxial active layer 103; and vice versa. In the embodiment, a light-emitting diode with the first conductivity type semiconductor layer 101 being n-type, and the second conductivity type semiconductor layer 102 being p-type is taken as an example.

The active layer 103 is an area providing light radiation for the recombination of the electrons and holes. Different materials of the active layer 103 can be selected according to different light-emitting wavelength. The active layer 103 can be a single heterostructure (SH), a double heterostructure (DH), a double-sided double heterostructure (DDH), or a multi-quantum well (MQW). The active layer 103 includes a well layer and a barrier layer, and the barrier layer has a larger band gap than the well layer. By adjusting a composition ratio of the semiconductor material in the active layer 103, it is expected to radiate light of different wavelengths. In the embodiment, the semiconductor epitaxial stack layer 100 is a semiconductor material layer that can radiate ultraviolet light, blue light, green light, yellow light, red light and infrared light. Specifically, the semiconductor epitaxial stack layer 100 can be a material covering the wavelength range of 200 nanometers (nm) to 950 nm. For example, common nitrides, such as gallium nitride-based semiconductor epitaxial stack layer 100. The gallium nitride-based semiconductor epitaxial stack layer 100 is commonly doped with aluminum (Al) and indium (In), and primarily provides radiation in the 200 nm to 550 nm wavelength range. Alternatively, common aluminum gallium indium phosphide (AlGaInP) or aluminum gallium arsenide (AlGaAs)-based semiconductor epitaxial stack layer 100 mainly provides radiation in the 550 nm to 950 nm wavelength range. In order to improve the light-emitting efficiency, it can be achieved by changing a depth of the quantum well, the number of layers, thickness and/or other features of the paired quantum wells and quantum barriers in the active layer 103. In the embodiment, the semiconductor epitaxial stack layer 100 is composed of AlGaInP-based or GaAs-based materials.

In order to improve current expansibility of the light-emitting diode, the current spreading layer 200 is disposed on a side of the second surface 120 of the semiconductor epitaxial stack layer 100, that is, disposed on the second conductivity type semiconductor layer 102, and a material of the current spreading layer 200 may be GaP, AlGaAs and AlGaInP. In the embodiment, the material of the current spreading layer 200 is GaP, and a thickness of the current spreading layer 200 is in a range of 0.02 μm to 1.5 μm. In an embodiment, the thickness of the current spreading layer 200 is in a range of 0.02 μm to 0.8 μm. In an embodiment, a doping concentration of the current spreading layer 200 is in a range of 5×10¹⁷ per cubic centimeter (5E17/cm³) to 5E18/cm³. Due to absorption effect of GaP on the light radiated by the active layer 103, the embodiment considers to reduce the GaP material layer to reduce the absorption of the light, to thereby improve the light-emitting efficiency of the LED chip (i.e., the light-emitting diode). As shown in FIG. 1, in the embodiment, the current spreading layer 200 is formed as a pattern current spreading layer, the pattern current spreading layer 200 defines multiple platform regions 202, recessed regions 201 are defined around each platform region 202, and the recessed regions are formed by removing a part of the current spreading layer 200.

In the embodiment, a depth of each recessed region 201 is smaller than the thickness of the current spreading layer 200. Specifically, the depth of each recessed region 201 is ⅓ to ⅔ of the thickness of the current spreading layer 200. Meanwhile, a projection area of the multiple platform regions 202 on the second surface 120 is controlled to be 5% to 50% of a surface area of the current spreading layer 200. The definitions of the depth of the recessed region 201 and the area ratio of the platform regions 202 can ensure that the current spreading layer 200 is removed as much as possible, thereby reducing the absorption of light, improving the light-emitting efficiency of the LED chip, and ensuring a sufficient current spreading effect of the patterned current spreading layer 200.

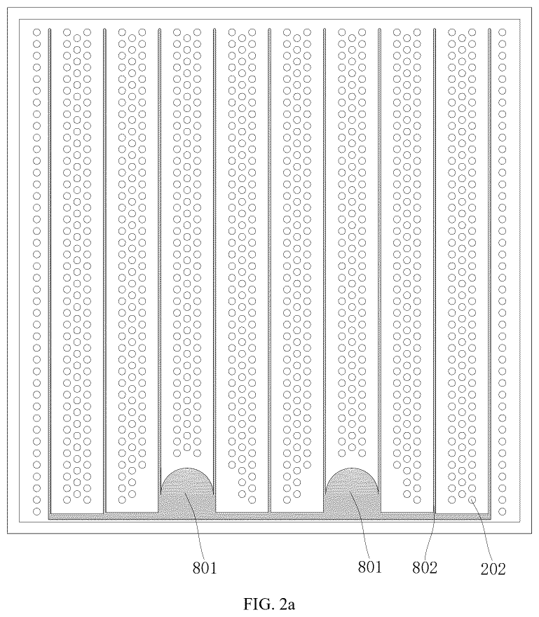

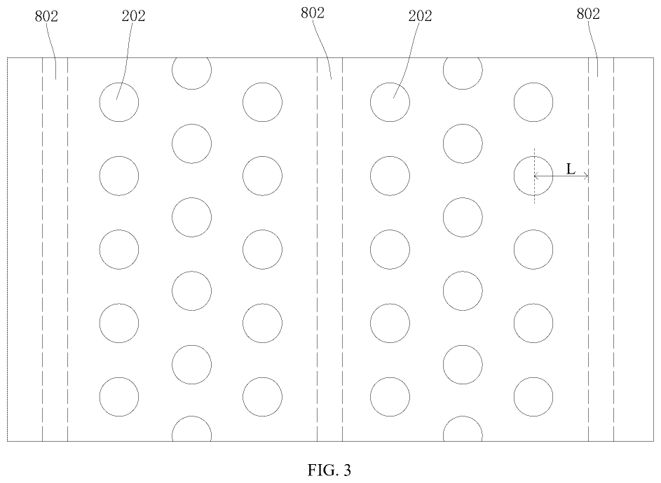

In the embodiment, as shown in FIG. 2a to FIG. 4, a distance between geometric centers of two adjacent platform regions 202 in the current spreading layer 200 is equal. A cross-sectional shape of each platform region of the current spreading layer 200 is a circle. As shown in FIG. 4, three platform regions 202 is taken as an example, a distance D of the geometric centers of adjacent first circular platform region 202-1, second circular platform region 202-2 and third circular platform region 202-3 is equal. In an optional embodiment, the distance D between the geometric centers of any two adjacent platform regions 202 is 1.2 to 3.2 times of a diameter of the circle. In an embodiment, the distance D between the geometric centers of any two adjacent platform regions 202 is 1.5 to 2.0 times of the diameter of the circle. The distance definition can optimize the size of the platform regions 202 and the distribution of the platform regions 202, and ensure good current spreading effect.

In an optional embodiment, a circumference 202-4 is formed with a geometric center of the first circular platform region 202-1 as a center and the aforementioned distance D as a radius. In the platform regions 202 adjacent to the first circular platform region 202-1, there are the geometric centers of 2k platform regions located on the circumference 202-4, and k is a natural number greater than or equal to 1, that is, there are geometric centers of an even number of platform regions located on the circumference of 202-4. In an embodiment, the geometric centers of the platform regions 202 adjacent to the first circular platform region 202-1 are located on the circumference 202-4. This ensures that when the current diffuses through each platform region 202, the overlapping area of current spreading between any two adjacent platform regions 202 is equal, thereby achieving the effect of uniform current diffusion.

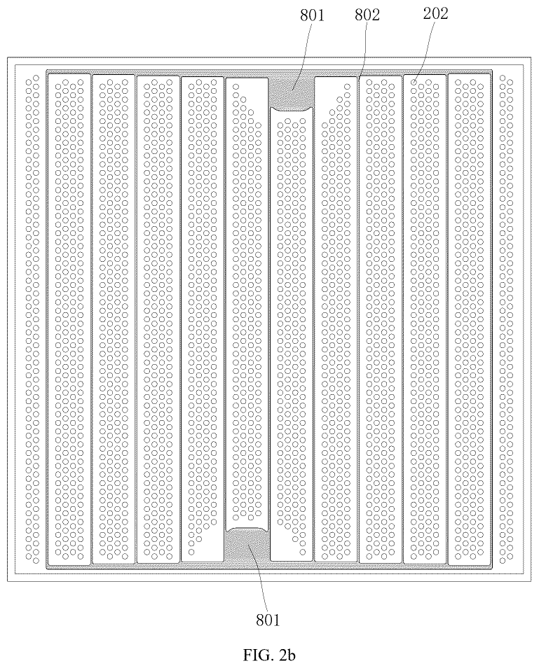

In an optional embodiment, as shown in FIG. 2a, FIG. 2b and FIG. 3, projections of the platform regions 202 of the current spreading layer 200 on the first surface 110 do not overlap with a projection of a first electrode 800 on the first surface 110. In an embodiment, as shown in FIG. 2a, in the projections on the first surface 110, a minimum spacing distance between the projections of the geometric centers of the platform regions 202 and projections of the expansion electrodes 802 is L, and the minimum spacing distance L is 1.2 to 3.2 times of a diameter of the circle of the platform regions 202, and further 1.5 to 2.5 times.

Referring to FIG. 1 again, the ohmic contact layer 300 is formed above the current spreading layer 200 facing away from the second surface 120 of the semiconductor epitaxial stack layer 100, and the ohmic contact layer 300 and the current spreading layer 200 form ohmic contact. Specifically, the ohmic contact layer 300 is located above the platform regions 202, the ohmic contact layer 300 can completely cover the platform regions 202, or partially cover the platform regions 202. Therefore, the ohmic contact layer 300 and the current spreading layer 200 are formed as patterned structures at the same time, which can reduce the absorbance of the ohmic contact layer 300. The above ohmic contact layer 300 is a transparent conductive layer, for example, it can be zinc oxide (ZnO), indium (III) oxide (In₂O₃), tin (IV) oxide (SnO₂), indium tin oxide (ITO), indium zinc oxide (IZO), gallium-doped zinc oxide (GZO), or any combination thereof. In the embodiment, the ohmic contact layer 300 is ITO.

As shown in FIG. 1, the light-transmissive dielectric layer 400 is formed on a side of the ohmic contact layer 300 facing away from the second surface 120, and is filled into the recessed regions 201 of the current spreading layer 200. The light-transmissive dielectric layer 400 at least covers the local surface and side surface of the ohmic contact layer 300 facing away from the semiconductor epitaxial stack layer 100. In an embodiment, the above light-transmissive dielectric layer 400 is not formed on surfaces of the platform regions 202 of the current spreading layer 200. The light-transmissive dielectric layer 400 defines multiple opening above the ohmic contact layer 300 to form multiple conductive through holes 401. The light-transmissive dielectric layer 400 is fluoride, oxide or nitride, specifically, at least one material selected from the group consisting of ZnO, silicon dioxide (SiO₂), silicon suboxide (SiOₓ), silicon oxynitride (SiOₓNy), silicon nitride (Si₃N₄), aluminum oxide (Al₂O₃), titanium oxide (TiOₓ), magnesium fluoride (MgF), and gallium fluoride (GaF). The light-transmissive dielectric layer 400 is used to reflect the light radiated by the active layer 103 to the semiconductor epitaxial stack layer 100 or the sidewall for emitting light. Therefore, the light-transmissive dielectric layer 400 directly in contact with the semiconductor epitaxial stack layer 100 is made of a low refractivity material, to increase the probability of light radiation being reflected when passing through the semiconductor epitaxial stack layer 100 to the surface of the light-transmissive dielectric layer 400. The refractivity of the light-transmissive dielectric layer 400 is below 1.5, such as SiO₂. A thickness of the light-transmissive dielectric layer 400 is above 100 nm, for example, 100 nm to 1000 nm. In an embodiment, 100 nm to 900 nm. In an embodiment, 300 nm to 900 nm. A transmittance of the light-transmissive dielectric layer is at least 70%, in an embodiment, above 80%, in an embodiment, 90%.

In an embodiment, the light-transmissive dielectric layer 400 includes a single layer or multiple layers of different materials, or is formed by repeatedly stacking the aforementioned insulating layer materials with two different refractivity. In an embodiment, an optical thickness of the light-transmissive dielectric layer 400 is in the range of an integer multiple of (light-emitting wavelength/4).

The reflecting layer 500 covers the light-transmissive dielectric layer 400, is filled into the conductive through holes 401, and is in contact with the ohmic contact layer 300, to achieve conduction and spreading of the current in the light-emitting diode. A cross-section area of the ohmic contact layer 300 is greater than a cross-section area of the conductive through holes 401 of the light-transmissive dielectric layer 400, which can maximize the mirror reflection area while ensuring a low voltage of the light-emitting diode, thereby improving the light-emitting brightness and light-emitting efficiency of the light-emitting diode. A reflectivity of the reflecting layer 500 is above 70%, and a material of the reflecting layer comprises at least one selected from the group consisting of silver (Ag), nickel (Ni), aluminum (Al), rhodium (Rh), palladium (Pd), iridium (Ir), ruthenium (Ru), magnesium (Mg), titanium (Ti), chromium (Cr), zinc (Zn), platinum (Pt), gold (Au), and hafnium (Hf), or an alloy thereof. In the embodiment, the material of the reflecting layer 500 is Au or Ag. The reflecting layer 500 can reflect the light radiated from the semiconductor epitaxial stack layer 100 toward the substrate 700 side back to the semiconductor epitaxial stack layer 100, and radiate from the light-emitting side (i.e., the first surface 110 side of the semiconductor epitaxial stack layer 100).

A cross-section of each conductive through hole 401 of the light-transmissive dielectric layer 400 may have any possible shape such as a circular, elliptical, polygonal cross section shape. A sidewall of each conductive through hole 401 is a vertical sidewall, or an inclined sidewall. A sidewall of each opening of the light-transmissive dielectric layer 400 is inclined, so that the reflecting layer 500 covers the sidewall of the opening. At the same time, the inclined sidewall can reflect the light radiated by the semiconductor epitaxial stack layer 100 to the light-emitting surface for emission.

Referring to FIG. 1, a substrate 700 is disposed on a side of the reflecting layer 500 facing away from the second surface 120, and a metal bonding layer 600 is disposed between the substrate 700 and the reflecting layer 500. The metal bonding layer 600 bonds the semiconductor epitaxial stack layer 100 onto the substrate 700. A material of the metal bonding layer 600 may any one or a combination of Au, tin (Sn), Ti, tungsten (W), Ni, Pt, and In, and the metal bonding layer 600 may be a single layer structure or a multi-layer structure. The substrate 700 is a conductive substrate 700, which can be a Si substrate 700 with conductive properties, a metal substrate 700, or other conductive substrates 700.

Referring to FIG. 1, FIG. 2a and FIG. 2b again, a first electrode 800 is located on the first surface 110 of the semiconductor epitaxial stack layer 100 and electrically connected to the first conductivity type semiconductor layer 101. The first electrode 800 includes a pad electrode 801 and multiple expansion electrodes 802. The first electrode 800 may be a single layer, a double-layer, or a multi-layer structure. In some optional embodiments, the pad electrode 801 can be designed as different shapes according to actual needs, such as a cylindrical shape, a square shape or other polygons, and the pad electrode 801 can be formed on any suitable positions such as the edge area and the middle area of the chip according to the needs of subsequent wire bonding and solid crystal. Optionally, as shown in FIG. 2a, the pad electrode 801 may include multiple regions defined on a same side of the chip. As shown in FIG. 2b, the pad electrode 801 may include multiple regions defined on opposite sides of the chip. The expansion electrodes 802 may be formed as a predetermined pattern shape. In an embodiment, the expansion electrodes 802 may be a strip structure parallel to each other, and an end of each expansion electrode 802 is electrically connected to the pad electrode 801. Specifically, materials of the pad electrode 801 and the expansion electrodes 802 are selected from the group consisting of germanium (Ge), Au and Ni, or any combination thereof, and may also include a metal material that can form a good ohmic contact with the semiconductor epitaxial stack layer 100.

A second electrode 900 is formed on a side of the substrate 700 facing away from the metal bonding layer 600, and the second electrode 900 is formed on the substrate 700 in a whole-surface covering form. A material of the second electrode 900 includes metal materials or metal alloy materials, specifically includes Au, Pt, germanium aluminum nickel (GeAlNi), Ti, beryllium gold (BeAu), germanium gold (GeAu), Al or zinc gold (ZnAu).

The embodiment defines that the distance between the geometric centers of the adjacent platform regions 202 in the current spreading layer 200 is equal, that is, a circle is drawn with the geometric center of any one platform region 202 as a center and the distance between the geometric centers of the adjacent platform regions 202 as a radius, the centers of the adjacent platform regions 202 are located on the circle. Thus, the adjacent platform regions 202 form a complementary pattern when the current spreads. Taking one platform region 202 as an example, an overlapping area of the current spread between any adjacent platform regions 202 is equal, thereby achieving the effect of uniform current diffusion. In addition, the formation of the aforementioned recessed regions 201 correspondingly reduce the content of the current spreading layer 200 (such as GaP), thereby reducing the light absorption of the current spreading layer 200 and increasing the light-emitting rate of the chip.

### Embodiment 2

The embodiment also provides a light-emitting diode, and the light-emitting diode of the embodiment also includes a semiconductor epitaxial stack layer 100, a current spreading layer 200, an ohmic contact layer 300, a light-transmissive dielectric layer 400, and a reflecting layer 500. The semiconductor epitaxial stack layer 100 has a first surface 110 and a second surface 120, and the first surface 110 is a light-emitting surface of the light-emitting diode. The semiconductor epitaxial stack layer 100 sequentially includes a first conductivity type semiconductor layer 101, an active layer 103 and a second conductivity type semiconductor layer 102 in a direction from the first surface 110 to the second surface 120. The current spreading layer 200 is located on a side of the second surface 120 of the semiconductor epitaxial stack layer 100. The ohmic contact layer 300 is located on a side of the current spreading layer 200 facing away from the second surface 120. The light-transmissive dielectric layer 400 is located on a side of the ohmic contact layer 300 facing away from the second surface 120. The reflecting layer 500 is located on a side of the ohmic contact layer 300 facing away from the second surface 120. The similarities with the embodiment 1 will not be repeated, but the differences are as follows.

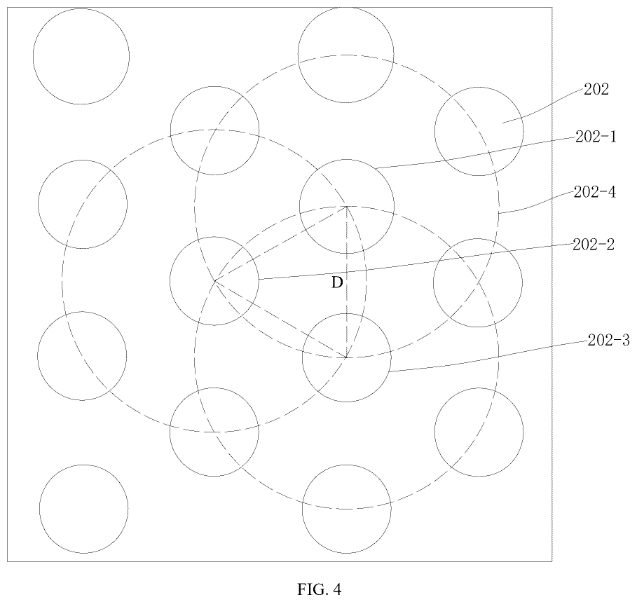

In the embodiment, a cross-sectional shape of each platform region 202 of the current spreading layer 200 is a regular polygon. For example, as shown in FIG. 5, is a regular hexagon. It can be understood that the cross-sectional shape of each platform region 202 of the current spreading layer 200 may be other shapes such as squares and regular octagons.

The cross-sectional shape of the platform region 202 of the current spreading layer 200 can be selected according to the specific structure of the LED chip and the material of the current spreading layer 200. Therefore, the cross-sectional shape of the platform region 202 of the current spreading layer 200 can be designed according to the specific LED chip to increase the applicability of the platform region.

### Embodiment 3

The embodiment also provides a light-emitting diode, and the light-emitting diode of the embodiment also includes a semiconductor epitaxial stack layer 100, a current spreading layer 200, an ohmic contact layer 300, a light-transmissive dielectric layer 400, and a reflecting layer 500. The semiconductor epitaxial stack layer 100 has a first surface 110 and a second surface 120, and the first surface 110 is a light-emitting surface of the light-emitting diode. The semiconductor epitaxial stack layer 100 sequentially includes a first conductivity type semiconductor layer 101, an active layer 103 and a second conductivity type semiconductor layer 102 in a direction from the first surface 110 to the second surface 120. The current spreading layer 200 is located on a side of the second surface 120 of the semiconductor epitaxial stack layer 100. The ohmic contact layer 300 is located on a side of the current spreading layer 200 facing away from the second surface 120. The light-transmissive dielectric layer 400 is located on a side of the ohmic contact layer 300 facing away from the second surface 120. The reflecting layer 500 is located on a side of the ohmic contact layer 300 facing away from the second surface 120. The similarities with the embodiment 1 and the embodiment 2 will not be repeated, but the differences are as follows.

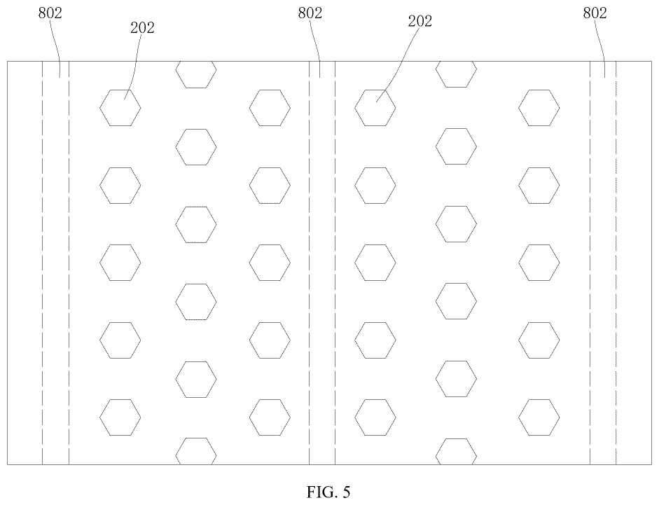

In the embodiment, as shown in FIG. 6, the recessed regions 201 of the current spreading layer 200 penetrates the current spreading layer 200, that is, a depth of each recessed region 201 is equal to a thickness of the current spreading layer 200. In this way, the material of the current spreading layer 200 can be further reduced, and the absorption of light can be further reduced, which is beneficial to improving the light-emitting efficiency of the LED chip. Especially for red-light chips, the GaP material layer as the current spreading layer 200 absorbs red-light particularly significantly. Therefore, when forming the recessed regions 201, the current spreading layer 200 is penetrated and removed from the recessed regions 201, thereby increasing the removed GaP material layer and reducing light absorption, while ensuring that the retained platform regions 202 can achieve uniform diffusion of current without affecting the photoelectric performance of the LED chip.

### Embodiment 4

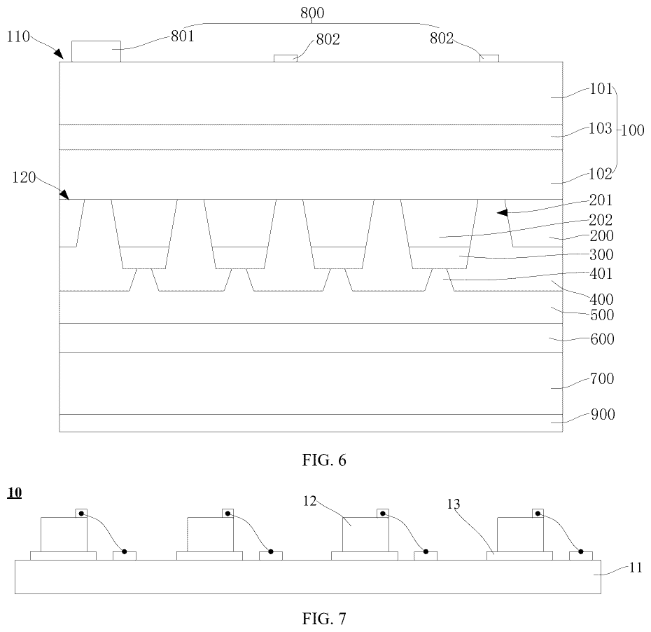

The embodiment provides a light-emitting device 10, as shown in FIG. 7, the light-emitting device 10 includes a circuit board 11 and at least one light-emitting element 12 fixed on the circuit board 11. The at least one light-emitting element 12 includes any one of the light-emitting diodes provides by the aforementioned embodiments 1 to 3. As shown in FIG. 7, an electrode of the light-emitting diode is directly and fixedly connected to a circuit layer 13 of the circuit board 11 through soldering, and another electrode of the light-emitting diode is connected to the circuit layer 13 of the circuit board 11 through a wire bonding process using a gold wire. Since the light-emitting device 10 includes the light-emitting diodes provided in the embodiments 1 to 3, it has a good light-emitting effect and better reliability.

The above embodiments are merely illustrative of the principles and effects of the disclosure and are not intended to limit the disclosure. Those skilled in the art may make various modifications and variations without departing from the spirit and scope of the disclosure. Such modifications and variations shall all fall within the scope defined by the appended claims.

What is claimed is:

1. A light-emitting diode, comprising:
a semiconductor epitaxial stack layer, having a first surface and a second surface opposite to each other, and comprising a first conductivity type semiconductor layer, an active layer and a second conductivity type semiconductor layer in a direction from the first surface to the second surface, wherein the first surface is a light-emitting surface;
a current spreading layer, located on a side of the second surface of the semiconductor epitaxial stack layer, wherein the current spreading layer is formed as a pattern current spreading layer, the pattern current spreading layer defines a plurality of platform regions, and recessed regions are defined around each of the plurality of platform regions;
an ohmic contact layer, located on a side of the plurality of platform regions facing away from the second surface;
a light-transmissive dielectric layer, located on a side of the ohmic contact layer facing away from the semiconductor epitaxial stack layer, and filled into the recessed regions, wherein the light-transmissive dielectric layer has a plurality of openings to define a plurality of conductive through holes; and
a reflecting layer, disposed on the light-transmissive dielectric layer, and filled into the plurality of conductive through holes, wherein the reflecting layer is electrically connected to the ohmic contact layer; and
wherein a distance between geometric centers of any two adjacent platform regions within the plurality of platform regions is equal.

2. The light-emitting diode as claimed in claim 1, wherein a cross-sectional shape of each of the plurality of platform regions is a circle or a regular polygon.

3. The light-emitting diode as claimed in claim 1, wherein the distance between the geometric centers of any two adjacent platform regions within the plurality of platform regions is in a range of 10 μm to 30 μm.

4. The light-emitting diode as claimed in claim 1, wherein the distance between the geometric centers of any two adjacent platform regions within the plurality of platform regions is D, a circle is drawn with a geometric center of any one of the plurality of platform regions as a center and the distance D as a radius, geometric centers of 2k of the plurality of platform regions are located on the circle, and k is a natural number greater than or equal to 1.

5. The light-emitting diode as claimed in claim 1, wherein a cross-sectional shape of each of the plurality of platform regions is a circle, and the distance between the geometric centers of any two adjacent platform regions within the plurality of platform regions is 1.2 to 3.2 times of a diameter of the circle.

6. The light-emitting diode as claimed in claim 1, wherein a projection area of the plurality of platform regions on the second surface is 5% to 50% of a surface area of the current spreading layer.

7. The light-emitting diode as claimed in claim 1, wherein the plurality of platform regions are defined in the current spreading layer, and a depth of each of the recessed regions is ⅓ to ⅔ of a thickness of the current spreading layer.

8. The light-emitting diode as claimed in claim 1, wherein the plurality of platform regions are defined in the current spreading layer, and a depth of each of the recessed regions is equal to a thickness of the current spreading layer.

9. The light-emitting diode as claimed in claim 1, further comprising a first electrode located on a side of the first surface and electrically connected to the first conductivity type semiconductor layer, wherein the first electrode comprises a pad electrode and expansion electrodes, the expansion electrodes are distributed on the side of the first surface, and when projected toward the first surface, projections of the expansion electrodes and the pad electrode do not overlap with a projection of the plurality of platform regions of the current spreading layer.

10. The light-emitting diode as claimed in claim 9, wherein a cross-sectional shape of each of the plurality of platform regions is a circle, and a minimum spacing distance between the projections of the expansion electrodes and projections of geometric centers of the plurality of platform regions is 1.2 to 3.2 times of a diameter of the circle.

11. The light-emitting diode as claimed in claim 1, further comprising:
a substrate, located on a side of the reflecting layer facing away from the second surface;
a metal bonding layer, located between the substrate and the reflecting layer; and
a second electrode, located on a side of the substrate facing away from the second surface, and electrically connected to the second conductivity type semiconductor layer.

12. The light-emitting diode as claimed in claim 1, wherein a sidewall of each of the plurality of platform regions is a vertical sidewall.

13. The light-emitting diode as claimed in claim 1, wherein a sidewall of each of the plurality of platform regions is an inclined sidewall.

14. The light-emitting diode as claimed in claim 13, wherein an opening size of a side of each of the plurality of platform regions facing away from the second surface is smaller than a bottom size of a side of the plurality of platform regions proximate to the second surface.

15. The light-emitting diode as claimed in claim 7, wherein the thickness of the current spreading layer is in a range of 0.02 μm to 1.5 μm.

16. The light-emitting diode as claimed in claim 1, wherein a thickness of the light-transmissive dielectric layer is above 100 nm, and transmittance of the light-transmissive dielectric layer is at least 70%.

17. The light-emitting diode as claimed in claim 1, wherein a cross-section area of the ohmic contact layer is greater than a cross-section area the plurality of conductive through holes of the light-transmissive dielectric layer.

18. The light-emitting diode as claimed in claim 1, wherein a reflectivity of the reflecting layer is above 70%, and a material of the reflecting layer comprises at least one selected from the group consisting of silver (Ag), nickel (Ni), aluminum (Al), rhodium (Rh), palladium (Pd), iridium (Ir), ruthenium (Ru), magnesium (Mg), titanium (Ti), chromium (Cr), zinc (Zn), platinum (Pt), gold (Au), and hafnium (Hf).

19. A light-emitting device, comprising a circuit board, and at least one light-emitting element located on the circuit board, wherein the at least one light-emitting element comprises the light-emitting diode as claimed in claim 1.

20. The light-emitting device as claimed in claim 19, wherein an electrode of the light-emitting diode is fixedly connected to a circuit layer of the circuit board through soldering, and another electrode of the light-emitting diode is connected to the circuit layer of the circuit board through a wire bonding process.
